(19) United States
(12) Patent Application Publication
(10) Pub. No.: US 2025/0212499 A1
(43) Pub. Date: Jun. 26, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Shunsuke ASABA, Himeji Hyogo (JP); Hiroshi KONO, Himeji Hyogo (JP)

(21) Appl. No.: 19/076,942

(22) Filed: Mar. 11, 2025

Related U.S. Application Data
(63) Continuation of application No. PCT/JP2024/005341, filed on Feb. 15, 2024.

(30) Foreign Application Priority Data
Sep. 4, 2023 (JP) 2023-143191

(51) Int. Cl. H10D 84/00; H10D 30/66; H10D 62/10; H10D 64/64

(52) U.S. Cl. CPC H10D 84/146; H10D 30/66; H10D 62/125; H10D 64/64

(57) ABSTRACT

According to one embodiment, a semiconductor device includes first to third electrodes, a first semiconductor portion provided between the first and second electrodes, a second semiconductor portion, and a fourth semiconductor portion. The first semiconductor portion includes first to sixth partial regions. The second partial region is aligned with the first partial region in a second direction crossing a first direction from the first electrode to the second electrode. The third partial region is aligned with the first partial region in the first direction. The fourth partial region is aligned with the second partial region in a third direction crossing a plane including the first and second directions. The fifth partial region is aligned with the fourth partial region in the first direction. The sixth partial region is aligned with the second partial region in the first direction and with the fourth partial region in the third direction.

### CROSS-REFERENCE TO RELATED APPLICATIONS

This is a continuation application of International Application PCT/JP2024/005341, filed on Feb. 15, 2024. This application also claims priority to Japanese Patent Application No. 2023-143191, filed on Sep. 4, 2023. The entire contents of which are incorporated herein by reference.

### FIELD

Embodiments described herein generally relate to a semiconductor device.

### BACKGROUND

There is a demand for improved characteristics in semiconductor devices having Schottky barrier diodes.

### BRIEF DESCRIPTION OF THE DRAWINGS

FIG. 1 is a schematic perspective view schematically showing an example of a semiconductor device according to an embodiment;

FIG. 2 is a view showing a part of the semiconductor device in FIG. 1;

FIG. 3 is a view showing a part of the semiconductor device in FIG. 1;

FIG. 4 is a view showing a part of the semiconductor device in FIG. 1;

FIG. 5 is a view showing a part of the semiconductor device in FIG. 1; and

FIG. 6 is a view showing an example of a side view of the semiconductor device in FIG. 1.

### DETAILED DESCRIPTION

According to one embodiment, a semiconductor device includes a first electrode, a second electrode, a first semiconductor portion of a first conductivity type provided between the first electrode and the second electrode, a second semiconductor portion of a second conductivity type, a fourth semiconductor portion of the first conductivity type, and a third electrode. The first semiconductor portion includes a first partial region, a second partial region, a third partial region, a fourth partial region, a fifth partial region, and a sixth partial region. The second partial region is aligned with the first partial region in a second direction. The second direction crosses a first direction from the first electrode to the second electrode. The third partial region is aligned with the first partial region in the first direction. The fourth partial region is aligned with the second partial region in a third direction. The third direction crosses a plane including the first direction and the second direction. The fifth partial region is aligned with the fourth partial region in the first direction and in Schottky contact with the second electrode. The sixth partial region is aligned with the second partial region in the first direction and aligned with the fourth partial region in the third direction. An impurity concentration of the first conductivity type in the sixth partial region is higher than a first impurity concentration of the first conductivity type in the first partial region, the second partial region, the third partial region, the fourth partial region, and the fifth partial region. The second semiconductor portion is provided between the sixth partial region and the second electrode and is aligned with the third partial region in the second direction. The fourth semiconductor portion is provided between the second semiconductor portion and the second electrode and is electrically connected to the second electrode. The third electrode is provided to face the third partial region and the second semiconductor section via a first insulating portion.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously in an antecedent drawing are marked with like reference numerals, and a detailed description is omitted as appropriate.

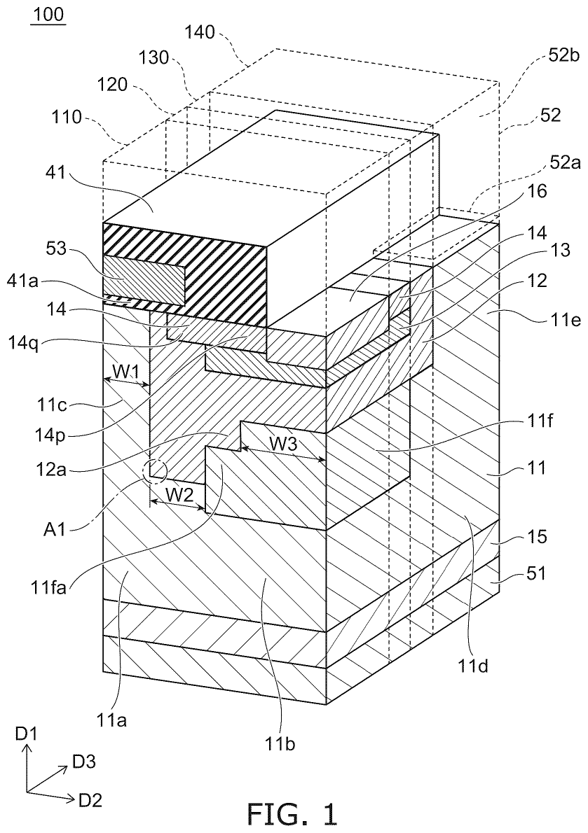

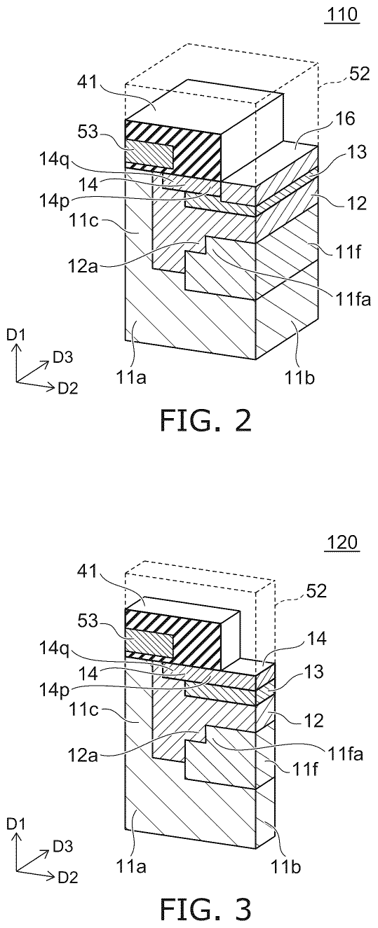

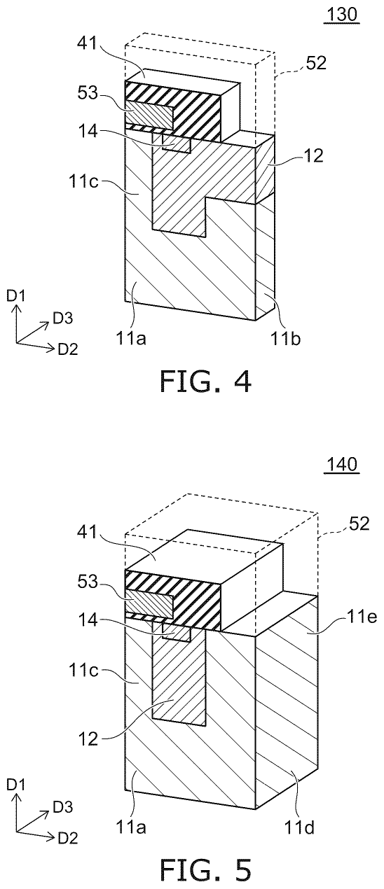

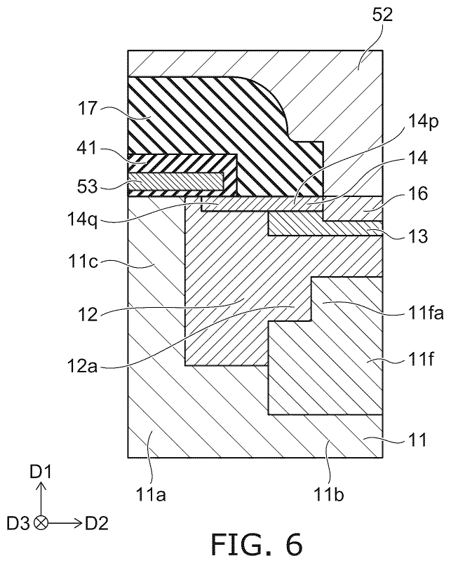

FIG. 1 is a schematic perspective view schematically showing an example of a semiconductor device 100. FIGS. 2 to 5 are views showing a part of the semiconductor device 100 of FIG. 1. FIG. 2 is a view showing a semiconductor section 110 that is a part of the semiconductor device 100. FIG. 3 is a view showing a semiconductor section 120 that is a part of the semiconductor device 100. FIG. 4 is a view showing a semiconductor section 130 that is a part of the semiconductor device 100. FIG. 5 is a view showing a semiconductor section 140 that is a part of the semiconductor device 100. FIG. 6 is a diagram showing an example of a side face of the semiconductor device 100 of FIG. 1.

The semiconductor device 100 includes a first electrode 51, a second electrode 52, a third electrode 53, a first semiconductor portion 11, a second semiconductor portion 12, a third semiconductor portion 13, and a fourth semiconductor portion 14. The semiconductor device 100 may include a fifth semiconductor portion 15, a silicide layer 16, and a first insulating portion 41. The first semiconductor portion 11, the second semiconductor portion 12, the third semiconductor portion 13, and the fourth semiconductor portion 14 include SiC. The first semiconductor portion 11, the second semiconductor portion 12, the third semiconductor portion 13, and the fourth semiconductor portion 14 may include at least one selected from the group consisting of 4H-SiC, 6H-SiC, and 3C-SiC. These semiconductor portions include crystals. These semiconductor portions may include silicon. These semiconductor portions may include a compound semiconductor including Ga.

A direction from the first electrode 51 to the second electrode 52 is defined as a first direction D1. One direction perpendicular to the first direction D1 is defined as a second direction D2. A third direction D3 is a direction perpendicular to the first direction D1 and the second direction D2.

FIGS. 2 to 5 show the semiconductor device 100 divided into the semiconductor section 110, the semiconductor section 120, the semiconductor section 130, and the semiconductor section 140 along the third direction D3. The semiconductor device 100 will be described below with reference to FIGS. 1 to 5. In FIGS. 2 to 5, illustrations of the fifth semiconductor portion 15 and the first electrode 51, which will be described later, are omitted.

The first semiconductor portion 11 is provided between the first electrode 51 and the second electrode 52. The first semiconductor portion 11 is of a first conductivity type. The first conductivity type is, for example, n-type.

The first semiconductor portion 11 includes a first partial region 11a, a second partial region 11b, a third partial region 11c, a fourth partial region 11d, a fifth partial region 11e, and a sixth partial region 11f. The second partial region 11b is aligned with the first partial region 11a in the second direction crossing the first direction D1 from the first electrode 51 to the second electrode 52. The third partial region 11c is aligned with the first partial region 11a in the first direction D1. The fourth partial region 11d is aligned with the second partial region 11b in the third direction D3 crossing a plane including the first direction D1 and the second direction D2. The fifth partial region 11e is aligned with the fourth partial region 11d in the first direction D1 and in Schottky contact with the second electrode 52. The fifth partial region 11e is aligned with the second partial region 11b in the first direction D1 and in the third direction D3. The sixth partial region is aligned with the second partial region 11b in the first direction D1 and aligned with the fourth partial region 11d in the third direction D3. The sixth partial region has an impurity concentration of the first conductivity type higher than a first impurity concentration of the first conductivity type in the first partial region 11a, the second partial region 11b, the third partial region 11c, the fourth partial region 11d, and the fifth partial region 11e. In the first partial region 11a, the second partial region 11b, the third partial region 11c, the fourth partial region 11d, the fifth partial region 11e, and the sixth partial region 11f, the boundaries may be clear or unclear. The above-mentioned plane extends in the first direction D1 and extends in the second direction D2.

For example, the first partial region 11a, the second partial region 11b, the third partial region 11c, the fourth partial region 11d, and the fifth partial region 11e are n-regions. The sixth partial region 11f is, for example, an n⁺-region. The sixth partial region 11f includes a first stepped portion 11fa. In the embodiment, as shown in FIGS. 1, 6, etc., the first stepped portion 11fa is formed in a step shape with respect to the second semiconductor portion 12 in a plane including the first direction D1 and the second direction D2.

A portion where the fifth partial region 11e and the second electrode 52 make Schottky contact functions as a Schottky barrier diode (SBD). As shown in FIG. 1, the second electrode 52 may include a first electrode portion 52a and a second electrode portion 52b. At least a part of the first electrode portion 52a is provided between the sixth partial region 11f and the second electrode portion 52b in the first direction D1. The first electrode portion 52a may include, for example, Ti. The second electrode portion 52b may include metal such as Al, for example.

The second semiconductor portion 12 is provided between the sixth partial region 11f and the second electrode 52. The second semiconductor portion 12 is aligned with the third partial region 11c in the second direction D2. In this embodiment, the second semiconductor portion 12 is provided above the sixth partial region 11f. Furthermore, in this embodiment, a part of the second semiconductor portion 12 is also provided above the second partial region 11b. The second semiconductor portion 12 is of a second conductivity type. The second conductivity type is, for example, p-type. When the first conductivity type is p-type, the second conductivity type is n-type. The second semiconductor portion 12 is, for example, a p⁺-region. The sixth partial region 11f is provided directly below the second semiconductor portion 12.

As shown in FIGS. 1, 6, etc., the second semiconductor portion 12 includes a second stepped portion 12a. In the present embodiment, the second stepped portion 12a is formed in a step shape with respect to the sixth partial region 11f in a plane including the first direction D1 and the second direction D2. In the plane, the second stepped portion 12a and the first stepped portion 11fa are opposed to each other. In the first stepped portion 11fa and the second stepped portion 12a, the boundary may be clear or unclear.

The third semiconductor portion 13 is provided between the second semiconductor portion 12 and the second electrode 52. In the third semiconductor portion 13, the direction from the third partial region 11c to the third semiconductor portion 13 is along the second direction D2. In this embodiment, the third semiconductor portion 13 is provided above the second semiconductor portion 12. The third semiconductor portion 13 is of the second conductivity type. In this embodiment, the second conductivity type is p-type. The impurity concentration of the second conductivity type in the third semiconductor portion 13 is higher than the impurity concentration of the second conductivity type in the second semiconductor portion 12. The third semiconductor portion 13 is, for example, a p⁺⁺-region. A part of the third semiconductor portion 13 is electrically connected to the second electrode 52. For example, the third semiconductor portion 13 makes ohmic contact with the second electrode 52. The third semiconductor portion 13 may be provided at a reasonable location considering the cell pitch, area, and positional relationship, and may be provided at the location shown in FIG. 1, for example. By providing the third semiconductor portion 13 at the position shown in FIG. 1, the photolithography process for providing the third semiconductor portion 13 can be shared with the process for the sixth partial region 11f.

The fourth semiconductor portion 14 is provided between the third semiconductor portion 13 and the second electrode 52. The fourth semiconductor portion 14 is electrically connected to the second electrode 52. In this embodiment, the fourth semiconductor portion 14 is provided above the second semiconductor portion 12 and above the third semiconductor portion 13. The direction from the third partial region 11c to the fourth semiconductor portion 14 is along the second direction D2. The fourth semiconductor portion 14 is of the first conductivity type. In this embodiment, the first conductivity type is n-type. The impurity concentration of the first conductivity type in the fourth semiconductor portion 14 is higher than the impurity concentration of the first conductivity type in the first semiconductor portion 11. The fourth semiconductor portion 14 is, for example, an n⁺⁺-region. A part of the fourth semiconductor portion 14 is electrically connected to the second electrode 52. For example, the fourth semiconductor portion 14 makes ohmic contact with the second electrode 52.

The direction from the first partial region 11a to the third electrode 53 is along the first direction D1. The first insulating portion 41 is provided around the third electrode 53. A part of the first insulating portion 41 is provided between the third partial region 11c and the third electrode 53. The first insulating portion 41 includes, for example, SiO₂.

For example, as shown in FIG. 2, the silicide layer 16 is provided in the semiconductor device 100. At least a part of the silicide layer 16 is provided between the second semiconductor portion 12 and the second electrode 52 in the first direction D1. At least a part of the silicide layer 16 is provided facing the fourth semiconductor portion 14 in the second direction D2. In this embodiment, the silicide layer 16 is provided above the upper face of the third semiconductor portion 13 and on the side face of the fourth semiconductor portion 14.

As shown in FIG. 1, the semiconductor device 100 may further include the first insulating portion 41. The first insulating portion 41 includes a first insulating region 41a. At least a part of the first insulating region 41a is provided between the third partial region 11c and the third electrode 53. The part of the first insulating portion 41 may be provided between the fourth semiconductor portion 14 and the third electrode 53.

A part of the third electrode 53 is provided above the upper face of the silicide layer 16. A part of the third electrode 53 is electrically connected to the fourth semiconductor portion 14 via the first insulating portion 41 on the upper face of the fourth semiconductor portion 14.

For example, as shown in FIG. 6, an insulating portion 17 may be provided between the fourth semiconductor portion 14, the first insulating portion 41, and the second electrode 52.

The fifth semiconductor portion 15 is provided between the first electrode 51 and the first semiconductor portion 11 in the first direction D1. The fifth impurity concentration of the first conductivity type in the fifth semiconductor portion 15 is higher than the first impurity concentration of the first semiconductor portion 11. The fifth semiconductor portion 15 may correspond to, for example, at least one of a buffer layer and a substrate. A low resistance electrical connection is obtained.

In the semiconductor device 100, the current flowing between the first electrode 51 and the second electrode 52 can be controlled by the potential of the third electrode 53. The potential of the third electrode 53 may be, for example, a potential based on the potential of the second electrode 52. The first electrode 51 functions, for example, as a drain electrode. The second electrode 52 functions, for example, as a source electrode. The third electrode 53 functions as, for example, a gate electrode. The semiconductor device 100 is, for example, a transistor. The semiconductor device 100 is, for example, a MOSFET (Metal-Oxide-Semiconductor Field Effect Transistor) having a built-in Schottky barrier diode.

In the semiconductor device 100, the sixth partial region 11f of an n⁺-region is provided adjacent to each of the second partial region 11b, the third partial region 11c, and the fifth partial region 11e. The sixth partial region 11f is provided directly below the second semiconductor portion 12, which is a p⁺-region. The sixth partial region 11f functions, for example, as a current spreading layer.

The third partial region 11c corresponds to, for example, a JFET (Junction Field Effect Transistor) region. In a case of a semiconductor device in which the sixth partial region 11f is provided directly below the third partial region 11c, the oxide film electric field increases. Therefore, it is necessary to take measures against avalanche breakdown, such as by narrowing the width W1 of the third partial region 11c in the second direction D2 or thickening the oxide film. In contrast, in this embodiment, the sixth partial region 11f is not provided directly below the third partial region 11c. Therefore, in the semiconductor device 100, the increase in the oxide film electric field can be suppressed without taking the above-mentioned measures.

Further, as shown in FIG. 1, the third partial region 11c and the sixth partial region 11f are spaced apart by a width W2 in the second direction D2. Width W2 is a finite distance. When the width W2 is 0, that is, in the case of a semiconductor device in which the third partial region 11c and the sixth partial region 11f are in contact with each other in the second direction D2, the breakdown voltage of the semiconductor device is determined based on the electric field concentrated in the region A1. In this case, the breakdown voltage is strongly influenced by variations in the width W1 in the second direction D2 of the third partial region 11c. In the semiconductor device 100 of the present embodiment, since the width W2 is provided and the third partial region 11c and the sixth partial region 11f are arranged apart from each other, avalanche breakdown can be induced in the first stepped portion 11fa and the second stepped portion 12a. Thereby, in the semiconductor device 100, the avalanche breakdown voltage can be stably decreased.

The fifth partial region 11e corresponds to, for example, a Schottky area. In the case of a semiconductor device in which the sixth partial region 11f is provided directly below the fifth partial region 11e, the electric field of the Schottky junction increases. In order to suppress this increase in the electric field, it is required, for example, to narrow the width W3 of the sixth partial region 11f in the second direction. In this embodiment, since the sixth partial region 11f is not provided directly below the fifth partial region 11e, in the semiconductor device 100, an increase in the electric field of the Schottky junction can be suppress.

In the semiconductor device 100, the SBD current can be spread along the third direction D3 without increasing the oxide film electric field. Furthermore, the breakdown voltage of the second stepped portion 12a (see FIG. 1) of the second semiconductor portion 12 is appropriately reduced by the sixth partial region 11f. For example, in the semiconductor device 100, avalanche resistance can be improved.

Further, in the semiconductor device 100, the first stepped portion 11fa of the sixth partial region 11f and the second stepped portion 12a of the second semiconductor portion 12 can improve the spread of the avalanche current. Thereby, in the semiconductor device 100, the effect of improving the avalanche resistance can be easily exhibited.

In the semiconductor device 100, the sixth partial region 11f is provided directly below the second semiconductor portion 12. When manufacturing the second semiconductor portion 12 and the sixth partial region 11f, a mask for implanting impurities can be shared. Thereby, in the semiconductor device 100, the sixth partial region 11f can be easily provided in the semiconductor device 100.

As shown in FIG. 1 etc., the fourth semiconductor portion 14 may include a high concentration region 14p and a low concentration region 14q. A part of the high concentration region 14p is provided between the low concentration region 14q and the silicide layer 16. The impurity concentration of the first conductivity type in the high concentration region 14p is higher than the impurity concentration of the first conductivity type in the low concentration region 14q. The high concentration region 14p is, for example, an n⁺⁺-region. The low concentration region 14q is, for example, an n⁺-region.

In the embodiment, for example, the first conductivity type impurity includes at least one selected from the group consisting of N, P, and As. For example, the second conductivity type impurity includes at least one selected from the group consisting of B, Al, and Ga.

In one example, the concentration of the first conductivity type impurity in the first semiconductor portion 11 is, for example, not less than 1×10¹⁴ cm⁻³ and not more than 1×10¹⁷ cm⁻³. In one example, the concentration of the second conductivity type impurity in the second semiconductor portion 12 is, for example, not less than 1×10¹⁶ cm⁻³ and not more than 1×10²⁰ cm⁻³. In one example, the concentration of the second conductivity type impurity in the third semiconductor portion 13 is, for example, not less than 1×10¹⁹ cm⁻³ and not more than 1×10²¹ cm⁻³. In one example, the concentration of the first conductivity type impurity in the fourth semiconductor portion 14 is, for example, not less than 1×10¹⁹ cm⁻³ and not more than 1×10²¹ cm⁻³. In one example, the concentration of the first conductivity type impurity in the fifth semiconductor portion 15 is, for example, not less than 1×10¹⁵ cm⁻³ and not more than 1×10¹⁸ cm⁻³. The above impurity concentration may be substantially a carrier concentration, for example.

In embodiments, information regarding length and thickness is obtained by electron microscopy or the like. Information regarding the composition of the material can be obtained by SIMS (Secondary Ion Mass Spectrometry) or EDX (Energy dispersive X-ray spectroscopy).

The embodiment includes the following aspects.

### Additional Note 1

A semiconductor device, comprising:
a first electrode;
a second electrode;
a first semiconductor portion of a first conductivity type, the first semiconductor portion being provided between the first electrode and the second electrode, the first semiconductor portion including
   a first partial region,
   a second partial region aligned with the first partial region in a second direction crossing a first direction from the first electrode to the second electrode,
   a third partial region aligned with the first partial region in the first direction,
   a fourth partial region aligned with the second partial region in a third direction crossing a plane including the first direction and the second direction,
   a fifth partial region aligned with the fourth partial region in the first direction and in Schottky contact with the second electrode, and
   a sixth partial region aligned with the second partial region in the first direction and aligned with the fourth partial region in the third direction, an impurity concentration of the first conductivity type being higher than a first impurity concentration of the first conductivity type in the first partial region, the second partial region, the third partial region, the fourth partial region, and the fifth partial region;
a second semiconductor portion of a second conductivity type, the second semiconductor portion being provided between the sixth partial region and the second electrode and being aligned with the third partial region in the second direction;
a fourth semiconductor portion of the first conductivity type, the fourth semiconductor portion being provided between the second semiconductor portion and the second electrode and being electrically connected to the second electrode; and
a third electrode provided to face the third partial region and the second semiconductor section via a first insulating portion.

### Additional Note 2

The semiconductor device according to Additional Note 1, further comprising:
a third semiconductor portion of the second conductivity type, the third semiconductor portion being provided between the second semiconductor portion and the second electrode,
a direction from the third partial region to the third semiconductor section being along the second direction.

### Additional Note 3

The semiconductor device according to Additional Note 1, further comprising:
the first insulating section,
at least a part of the first insulating portion being provided between the third partial region and the third electrode.

### Additional Note 4

The semiconductor device according to Additional Note 2 or 3, wherein
an impurity concentration of the first conductivity type in the fourth semiconductor portion is higher than the first impurity concentration, and
an impurity concentration of the second conductivity type in the third semiconductor portion is higher than an impurity concentration of the second conductivity type in the second semiconductor portion.

### Additional Note 5

The semiconductor device according to any one of Additional Notes 1-4, further comprising:
a silicide layer,
a part of the silicide layer being provided between the second semiconductor portion and the second electrode in the first direction to face the fourth semiconductor section in the second direction.

### Additional Note 6

The semiconductor device according to any one of Additional Notes 1-5, wherein
the fourth semiconductor portion includes a high concentration region and a low concentration region,
a part of the high concentration region is provided between the low concentration region and the silicide layer in the second direction, and
an impurity concentration of the first conductivity type in the high concentration region is higher than an impurity concentration of the first conductivity type in the low concentration region.

### Additional Note 7

The semiconductor device according to additional Notes 1-6, wherein
the sixth partial region includes a first stepped portion, and
the first stepped portion is in a stepped shape with respect to the second semiconductor portion in a plane including the first direction and the second direction.

### Additional Note 8

The semiconductor device according to any one of Additional Notes 1-7, wherein
the second semiconductor portion includes a second stepped portion, and
the second stepped portion is in a stepped shape with respect to the sixth partial region in a plane including the first direction and the second direction.

### Additional Note 9

The semiconductor device according to any one of Additional Notes 1-8, wherein
the sixth partial region includes a first stepped portion,
the first stepped portion is in a stepped shape with respect to the second semiconductor portion in a plane including the first direction and the second direction.
the second semiconductor portion includes a second stepped portion,
the second stepped portion is in a stepped shape with respect to the sixth partial region in the plane including the first direction and the second direction, and
the first stepped portion and the second stepped portion are opposed to each other.

### Additional Note 10

The semiconductor device according to any one of Additional Notes 2-9, wherein
a part of the third semiconductor portion and a part of the fourth semiconductor portion are in ohmic contact with the second electrode.

### Additional Note 11

The semiconductor device according to any one of Additional Notes 1-10, wherein
the second electrode includes a first electrode portion and a second electrode portion, and
the first electrode portion is provided between the fifth partial region and the second electrode portion in the first direction.

### Additional Note 12

The semiconductor device according to any one of Additional Notes 11 wherein
at least a part of the first electrode portion is provided between the sixth partial region and the second electrode portion in the first direction.

### Additional Note 13

The semiconductor device according to Additional Note 11, wherein
the first electrode portion includes Ti.

### Additional Note 14

The semiconductor device according to Additional Note 11, wherein
the second electrode portion includes Al.

### Additional Note 15

The semiconductor device according to any one of Additional Notes 1-14, further comprising:
a fifth semiconductor portion of the first conductivity type,
the fifth semiconductor section being provided between the first electrode and the first semiconductor section in the first direction, and
an impurity concentration of the first conductivity type in the fifth semiconductor portion being higher than the first impurity concentration.

### Additional Note 16

The semiconductor device according to any one Additional Notes 2-15, wherein
the first semiconductor portion, the second semiconductor portion, the third semiconductor portion, and the fourth semiconductor portion include SiC.

According to the embodiment, a semiconductor device with improved characteristics can be provided.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as electrodes, semiconductor portions, insulating portions, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode;
a first semiconductor portion of a first conductivity type, the first semiconductor portion being provided between the first electrode and the second electrode, the first semiconductor portion including
a first partial region,
a second partial region aligned with the first partial region in a second direction crossing a first direction from the first electrode to the second electrode,
a third partial region aligned with the first partial region in the first direction,
a fourth partial region aligned with the second partial region in a third direction crossing a plane including the first direction and the second direction,
a fifth partial region aligned with the fourth partial region in the first direction and in Schottky contact with the second electrode, and
a sixth partial region aligned with the second partial region in the first direction and aligned with the fourth partial region in the third direction, an impurity concentration of the first conductivity type being higher than a first impurity concentration of the first conductivity type in the first partial region, the second partial region, the third partial region, the fourth partial region, and the fifth partial region;
a second semiconductor portion of a second conductivity type, the second semiconductor portion being provided between the sixth partial region and the second electrode and being aligned with the third partial region in the second direction;
a fourth semiconductor portion of the first conductivity type, the fourth semiconductor portion being provided between the second semiconductor portion and the second electrode and being electrically connected to the second electrode; and
a third electrode provided to face the third partial region and the second semiconductor section via a first insulating portion.

2. The device according to claim 1, further comprising:
a third semiconductor portion of the second conductivity type, the third semiconductor portion being provided between the second semiconductor portion and the second electrode,
a direction from the third partial region to the third semiconductor section being along the second direction.

3. The device according to claim 2, wherein
an impurity concentration of the first conductivity type in the fourth semiconductor portion is higher than the first impurity concentration, and
an impurity concentration of the second conductivity type in the third semiconductor portion is higher than an impurity concentration of the second conductivity type in the second semiconductor portion.

4. The device according to claim 1, further comprising:
a silicide layer,
a part of the silicide layer being provided between the second semiconductor portion and the second electrode in the first direction to face the fourth semiconductor section in the second direction.

5. The device according to claim 4, wherein
the fourth semiconductor portion includes a high concentration region and a low concentration region,
a part of the high concentration region is provided between the low concentration region and the silicide layer in the second direction, and
an impurity concentration of the first conductivity type in the high concentration region is higher than an impurity concentration of the first conductivity type in the low concentration region.

6. The device according to claim 1, wherein
the sixth partial region includes a first stepped portion, and
the first stepped portion is in a stepped shape with respect to the second semiconductor portion in a plane including the first direction and the second direction.

7. The device according to claim 1, wherein
the second semiconductor portion includes a second stepped portion, and
the second stepped portion is in a stepped shape with respect to the sixth partial region in a plane including the first direction and the second direction.

8. The device according to claim 1, wherein
the sixth partial region includes a first stepped portion,
the first stepped portion is in a stepped shape with respect to the second semiconductor portion in a plane including the first direction and the second direction,
the second semiconductor portion includes a second stepped portion,
the second stepped portion is in a stepped shape with respect to the sixth partial region in the plane including the first direction and the second direction, and
the first stepped portion and the second stepped portion are opposed to each other.

9. The device according to claim 2, wherein
a part of the third semiconductor portion and a part of the fourth semiconductor portion are in ohmic contact with the second electrode.

10. The device according to claim 2, wherein
the first semiconductor portion, the second semiconductor portion, the third semiconductor portion, and the fourth semiconductor portion include SiC.

11. The device according to claim 1, further comprising:
the first insulating section,
at least a part of the first insulating portion being provided between the third partial region and the third electrode.

12. The device according to claim 1, wherein
the second electrode includes a first electrode portion and a second electrode portion, and
the first electrode portion is provided between the fifth partial region and the second electrode portion in the first direction.

13. The device according to claim 12, wherein
at least a part of the first electrode portion is provided between the sixth partial region and the second electrode portion in the first direction.

14. The device according to claim 12, wherein
the first electrode portion includes Ti.

15. The device according to claim 12, wherein
the second electrode portion includes Al.

16. The device according to claim 1, further comprising:
a fifth semiconductor portion of the first conductivity type,
the fifth semiconductor section being provided between the first electrode and the first semiconductor section in the first direction, and
an impurity concentration of the first conductivity type in the fifth semiconductor portion being higher than the first impurity concentration.
